(19) United States
(12) Patent Application Publication
(10) Pub. No.: US 2025/0311247 A1
(43) Pub. Date: Oct. 2, 2025

(54) DIELECTRIC STACK OF MIM CAPACITORS

(71) Applicant: TAIWAN SEMICONDUCTOR MANUFACTURING COMPANY, LTD., Hsinchu (TW)

(72) Inventors: Bi-Shen LEE, Hsinchu (TW); Yi-Yang WEI, Hsinchu (TW); Hai-Dang TRINH, Hsinchu (TW); Chung-Yi YU, Hsinchu City (TW); Cheng-Yuan TSAI, Hsinchu County (TW)

(73) Assignee: TAIWAN SEMICONDUCTOR MANUFACTURING COMPANY, LTD., Hsinchu (TW)

(21) Appl. No.: 18/623,955

(22) Filed: Apr. 1, 2024

(51) Int. Cl. H01L 23/00; H01L 23/522; H01L 25/18

(52) U.S. Cl. CPC H10D 1/042; H01L 23/5223; H01L 24/05; H01L 24/13; H01L 25/18; H10D 1/714; H10D 1/716; H01L 2224/05541; H01L 2224/05571; H01L 2224/05583; H01L 2224/13006; H01L 2224/13007

(57) ABSTRACT

A method of forming a capacitor includes the following steps. A first electrode is formed over a substrate. A first dielectric layer is formed over the first electrode. A second dielectric layer is formed over the first dielectric layer. The first dielectric layer has a conduction band barrier height higher than a conduction band barrier height of the second dielectric layer. A second electrode is formed over the second dielectric layer.

### BACKGROUND

Metal-Insulator-Metal (MIM) capacitors have been widely used in functional circuits such as mixed signal circuits, analog circuits, Radio Frequency (RF) circuits, Dynamic Random-Access Memories (DRAMs), embedded DRAMs, and logic operation circuits. For example, in system-on-chip applications, different capacitors for different functional circuits may be used to serve different purposes. In mixed-signal circuits, capacitors may also be used as decoupling capacitors and high-frequency noise filters. For DRAM and embedded DRAM circuits, capacitors may be used for memory storage, while for RF circuits, capacitors may be used in oscillators and phase-shift networks for coupling and/or bypassing purposes. For microprocessors, capacitors may be used for decoupling.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a package component including one or a plurality of Metal-Insulator-Metal (MIM) capacitors in accordance with some embodiments.

FIGS. 2-7, 8A and 9-15 illustrate the cross-sectional views of intermediate stages in the formation of a MIM capacitor in accordance with some embodiments.

FIG. 8B shows a band diagram of a portion of the MIM capacitor in accordance with some embodiments.

FIGS. 16-19 illustrate cross-sectional views of intermediate stages in the formation of a deep trench capacitor (DTC) in accordance with some embodiments.

FIGS. 20-21 illustrate cross-sectional views of a semiconductor structure in accordance with some embodiments.

FIG. 22 illustrates a cross-sectional view of a 3D IC structure in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A capacitance of a capacitor is in positive relation to a dielectric constant of the dielectric material of the capacitor. In a Metal-Insulator-Metal (MIM) capacitor, a high-k material is selected to achieve high capacitance. However, it may results in breakdown voltage (V_{BD}) and Leakage current (I_{LK}) degradation.

Some embodiments in accordance of the present disclosure provide a dielectric structure with a suitable interface band diagram to improve a performance of the MIM capacitor. The dielectric structure is a multilayer structure including a first dielectric layer, a second dielectric layer and a third dielectric layer in which the second dielectric layer is sandwiched between the first dielectric layer and the third dielectric layer. The second dielectric layer has a k-value greater than the first and third dielectric layers. The first dielectric layer and the third dielectric layer each include higher conduction band barrier height than the second dielectric layer to avoid leakage current and improve reliability of the MIM capacitor.

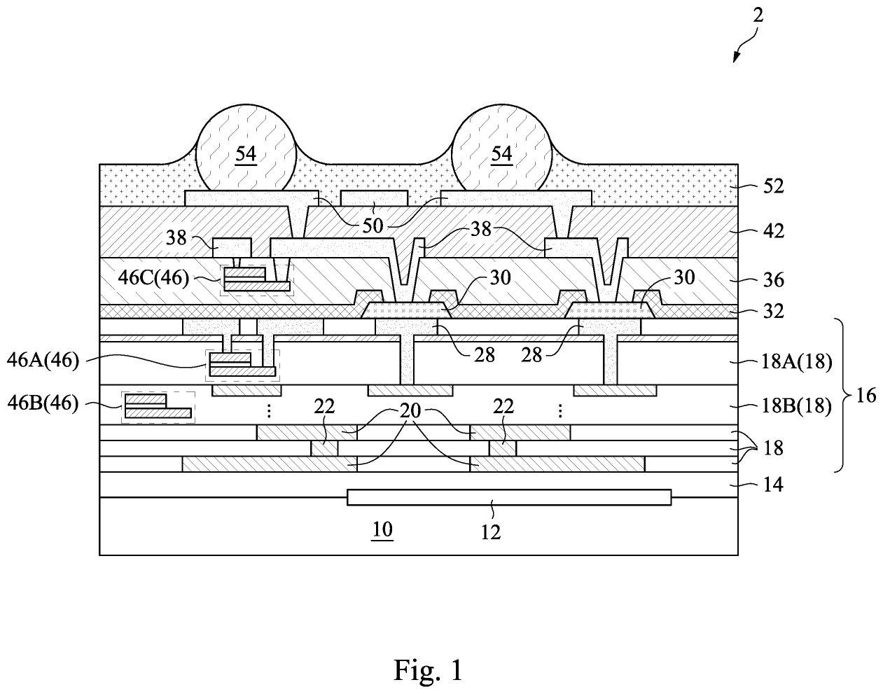

FIG. 1 illustrates a cross-sectional view of package component 2 including a capacitor(s) therein. The package component 2 may be a device wafer, an interposer wafer, a package (such as an Integrated Fan-Out (InFO) package), or the like. In the subsequently illustrated embodiments, a device wafer is used as an example, and capacitors may be formed in the back-end redistribution structure of the device wafer, while the capacitor(s) may be formed in other structures. An example structure of the package component 2 is discussed herein to show where a capacitor(s) may be formed. The capacitors in accordance with the embodiments of the present disclosure, however, are not limited to the illustrative structure of the package component 2.

Referring to FIG. 1, the package component 2 includes a semiconductor substrate 10. In accordance with some embodiments, the semiconductor substrate 10 is a bulk silicon substrate or a silicon-on-insulator substrate. In accordance with alternative embodiments of the present disclosure, other semiconductor materials that include group III, group IV, and/or group V elements may also be used, which may include silicon germanium, carbon-doped silicon, and/or III-V compound semiconductor materials. Integrated circuit devices 12, which may include active devices such as transistors are formed at a surface of semiconductor substrate 10.

The package component 2 may further include an Inter-Layer Dielectric (ILD) 14 and an interconnect structure 16 over the semiconductor substrate 10. The interconnect structure 16 includes metal lines 20 and vias 22, which are formed in dielectric layers 18. The dielectric layer 18 includes a dielectric layer 18A and a dielectric layer 18B under the dielectric layer 18A. The metal lines at a same level are collectively referred to as being a metal layer hereinafter. Accordingly, the interconnect structure 16 may include a plurality of metal layers that are interconnected through vias 22. The metal lines 20 and the vias 22 may be formed of copper or copper alloys, although they can also be formed of other metals. In accordance with some embodiments, the dielectric layers 18 are formed of low-k dielectric materials. The dielectric constants (k values) of the low-k dielectric materials may be lower than about 3.5, or lower than about 3.0, for example. Metal pads 28 are formed in the dielectric layer 18.

Metal pads 30 are formed over the interconnect structure 16, and may be electrically coupled to an integrated circuit device 12 through metal lines 20 and vias 22. The metal pads 30 may be aluminum pads or aluminum-copper pads, and hence are alternatively referred to as aluminum pads 30 hereinafter, while other metallic materials may be used. In accordance with some embodiments, the metal pads 30 are in physical contact with the underlying metal vias or metal lines (or pads) in the top metal layer in the interconnect structure 16. For example, as shown in FIG. 1, the metal pads 30 have bottom surfaces in contact with top surfaces of metal pads 28.

As also shown in FIG. 1, a passivation layer 32 is formed over the interconnect structure 16. The passivation layer 32 has a k value equal to or greater than 3.8, and is formed using a non-low-k dielectric material(s). In accordance with some embodiments, the passivation layer 32 is a composite layer including a silicon oxide layer (not shown), and a silicon nitride layer (not shown) over the silicon oxide layer. The passivation layer 32 may also be formed of other non-porous dielectric materials such as Un-doped Silicate Glass (USG), silicon oxynitride, and/or the like.

The passivation layer 32 is patterned, so that some portions of the passivation layer 32 cover the edge portions of the metal pads 30, and some middle portions of the metal pads 30 are exposed through the openings in the passivation layer 32. The passivation layer 32 and the metal pads 30 may have some portions level with each other in accordance with some embodiments.

A polymer layer 36 is formed over the metal pads 30 and the passivation layer 32. In accordance with some embodiments, the polymer layer 36 is formed of polybenzoxazole (PBO). In accordance with alternative embodiments, the polymer layer 36 is formed of other polymers such as polyimide, benzocyclobutene (BCB), or the like. The material of the polymer layer 36 may be photo sensitive, although non-photo-sensitive materials may also be used.

A Post-Passivation Interconnect (PPI) 38 may formed, which includes line portions over the polymer layer 36, and via portions extending into the polymer layer 36. The PPI 38 is thus electrically connected to the metal pads 30. The PPI 38 may be formed of copper or a copper alloy, for example.

A polymer layer 42 is formed over the polymer layer 36 and the PPI 38. In accordance with some embodiments, the polymer layer 42 is formed of a polymer such as PBO, polyimide, BCB, or the like. The material of the polymer layer 42 may be photo sensitive, although non-photo-sensitive materials may also be used. The polymer layers 36 and 42 may be formed of a same type of polymer, or may be formed of different types of polymers.

A PPI 50 is formed over the polymer layer 42, and is electrically connected to the PPI 38 and the integrated circuit device 12. The PPI 50 includes a plurality of redistribution lines. In accordance with some embodiments, the PPI 50 is in dielectric layer 52, which encircles the PPI 50, and contacts the top surface of the polymer layer 42. The dielectric layer 52 may be a molding compound, a polymer layer, or the like. The top surfaces and the sidewalls of the PPI 50 may also be in physical contact with the dielectric layer 52.

In accordance with some embodiments, electrical connectors 54 are formed to electrically connect to the PPI 50. The electrical connectors 54 may include metal regions, which may include solder balls placed on the PPI 50. The electrical connectors 54 may also include metal pillars. In the embodiments in which the electrical connectors 54 include solder, the solder may be placed or plated, and the plating of solder may be similar to the formation of the PPI 38. The electrical connectors 54 have upper portions over the top surface of the dielectric layer 52, and lower portions embedded in the dielectric layer 52. After the formation of the electrical connectors 54, the package component 2 may be sawed into individual package components (which may be device dies), each including the integrated circuit device 12 and one capacitor 46 or a plurality of capacitors 46.

In accordance with some embodiments, one or more capacitor 46 (represented by 46A, 46B, and 46C) are formed in one of the dielectric layers 18, or in the polymer layer 36 or 42. For example, the capacitor 46 may be in the dielectric layer 18A which is underlying the passivation layer 32, as represented by capacitor 46A. The capacitor 46 may also be in a dielectric layer under the top dielectric layer, as represented by a capacitor 46B. The capacitor 46 may also be in a polymer layer such as the polymer layer 36 or 42, as represented by capacitor 46C. In accordance with some embodiments, the capacitor 46 is a decoupling capacitor, with the top electrode and the bottom electrode of the capacitor 46 being electrically coupled to power supply lines such as VDD and VSS. Accordingly, the capacitor 46 is used to filter noise and/or also used as a power storage for reducing the voltage variation resulted from the current-drawn from the power source.

In accordance with alternative embodiments, the top electrode and the bottom electrode of the capacitor 46 are connected to signal lines, and the capacitor 46 is used to filter noise. The top electrode and the bottom electrode of the capacitor 46 are connected to contact plugs, as will be provided in the subsequently discussed process flow. In accordance with alternative embodiments, the capacitor 46 is used for other purposes such as in Dynamic Random-Access Memory (DRAM) cells.

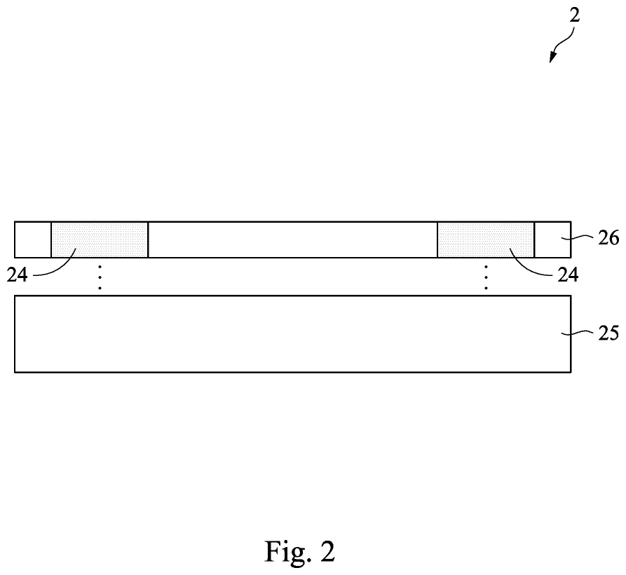

FIGS. 2-8A and 9-15 illustrate cross-sectional views of intermediate stages in the formation of the capacitor 46 in the package component 2 in accordance with some embodiments. The process shown in FIGS. 2 through 15 may represent the process for forming the capacitor 46A in the dielectric layer 18A as shown in FIG. 1. The concept of the example embodiments may be used for forming capacitors in various layers, such as what are represented by the capacitors 46B and 46C in FIG. 1.

Referring to FIG. 2, conductive features 24 are illustrated forming in a dielectric layer 26. Portions of the package component 2 underlying the conductive features 24 are represented as features 25. The details of the features 25 are not illustrated, and may be found referring to FIG. 1. In accordance with some embodiments in which the capacitor 46A (FIG. 1) is to be formed, the conductive features 24 are the metal lines or metal pads formed in the dielectric layer 18B (FIG. 1). In accordance with alternative embodiments in which the capacitor 46B (FIG. 1) is to be formed, the conductive features 24 are the metal lines or metal pads underlying the dielectric layer 18B. In accordance with yet other embodiments in which the capacitor 46C (FIG. 1) is to be formed, conductive features 24 are the metal pads 30 or some portions of the PPI 38.

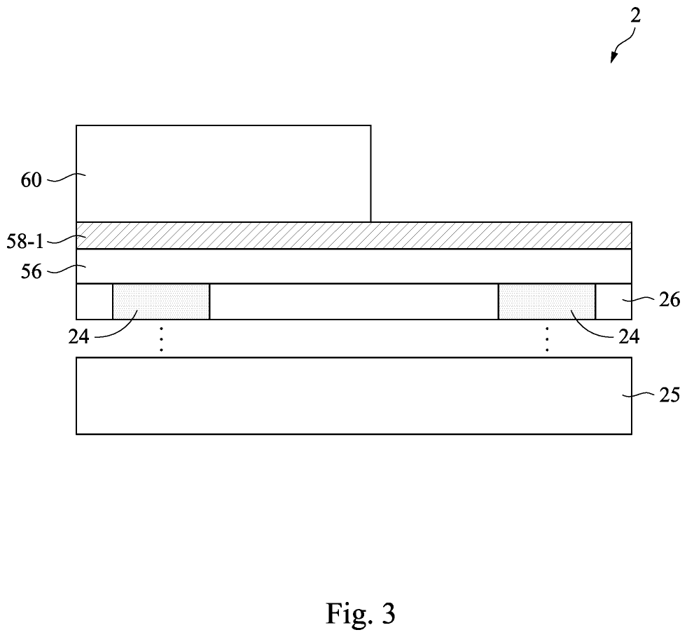

Referring to FIG. 3, a dielectric layer 56 is formed over the conductive features 24. Although not shown, an etch stop layer may be (or may not be) formed between the conductive features 24 and the dielectric layer 56. Depending on the position, the dielectric layer 56 may be formed of an inorganic material such as USG, silicon carbide, silicon carbo-nitride (SiCN), silicon oxide, silicon nitride, or the like, combinations thereof, and/or multi-layers thereof. The dielectric layer 56 may be formed using Plasma Enhance Chemical Vapor Deposition (PECVD), Low-Pressure Chemical Vapor Deposition (LPCVD), Atomic Layer Deposition (ALD), or the like.

Next, a capacitor electrode 58-1 is deposited as a blanket layer. The capacitor electrode 58-1 is formed of a conductive material. For example, the capacitor electrode 58-1 may be formed of or include a metal nitride such as titanium nitride (TiN), tantalum nitride (TaN), or the like. The deposition process may include ALD, Chemical Vapor Deposition (CVD), PECVD, or the like.

An etching mask 60 is then formed, and is patterned. In accordance with some embodiments, the etching mask 60 includes a photoresist. Next, an etching process is performed to pattern the capacitor electrode 58-1. In accordance with some embodiments, the etching is performed through a dry etching process. The etching gas may include a chlorine-based gas such as TiCl₄, TaCl₄, WCl₄, chlorine (Cl₂), and/or the like. The etching gas may also include a fluorine-containing gas such as CHF₃, CF₄, or the like, or the combination of the aforementioned gases. Oxygen (O₂) may also be included in the etching gas.

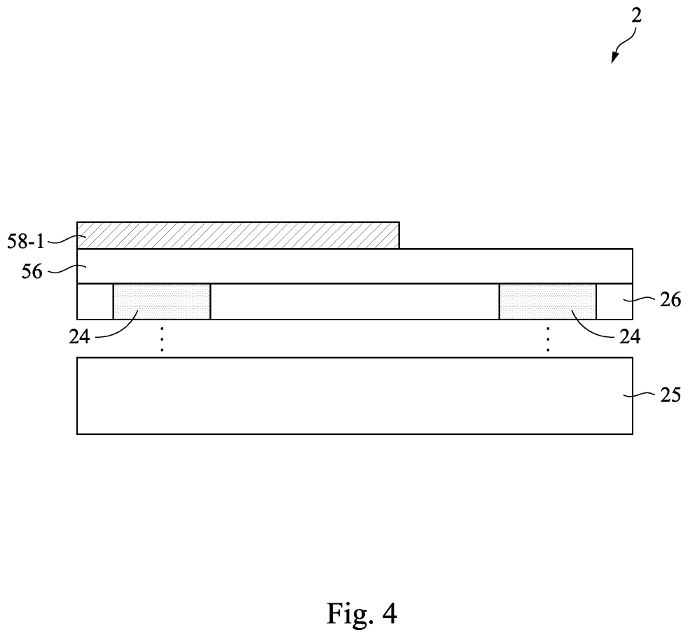

In accordance with alternative embodiments, the etching is performed through a wet etching process. The etching chemical may include the mixture of NH₄OH (ammonia water) and H₂O₂, the mixture of H₂O₂ and H₂O, and/or the like. The etching mask 60 is then removed, and the resulting structure is shown in FIG. 4. A cleaning process, which may be a wet process, may be performed to remove by-products.

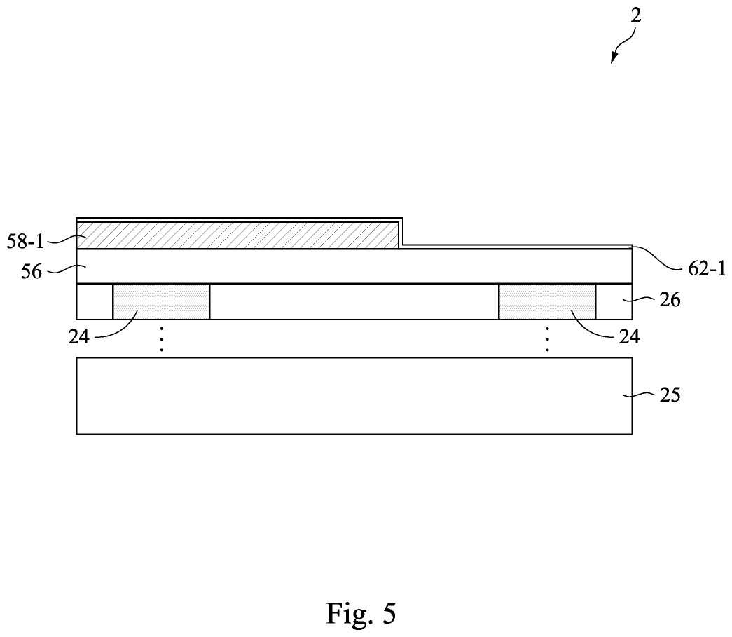

Reference is made to FIG. 5. A first dielectric layer 62-1 is formed on the capacitor electrode 58-1 and the dielectric layer 56. The formation process of the first dielectric layer 62-1 may include ALD, CVD, or the like. In some embodiments, the first dielectric layer 62-1 extends over a top surface of the capacitor electrode 58-1, along a sidewall of the capacitor electrode 58-1 and over a top surface of the dielectric layer 56.

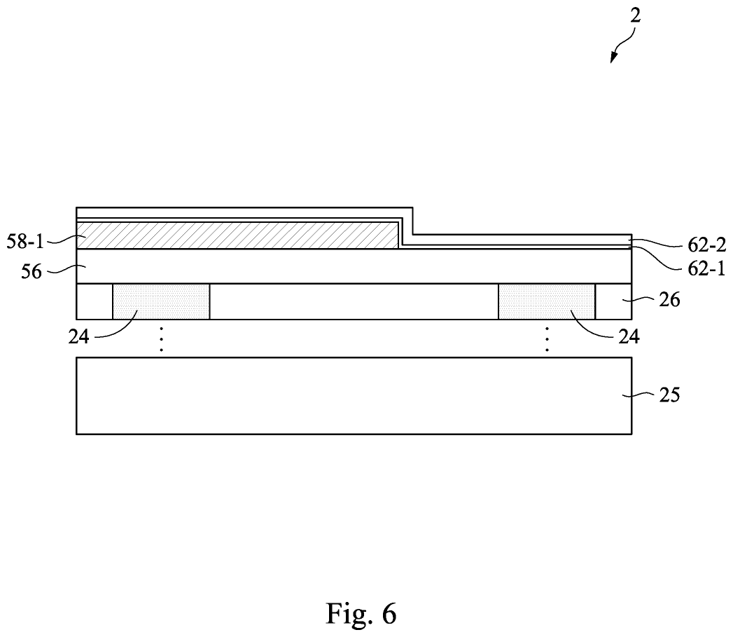

Reference is made to FIG. 6. A second dielectric layer 62-2 is formed on the first dielectric layer 62-1. In some embodiments, the formation process of the second dielectric layer 62-2 may include ALD, CVD, or the like. The second dielectric layer 62-2 and the first dielectric layer 62-1 include different compositions and different k-values.

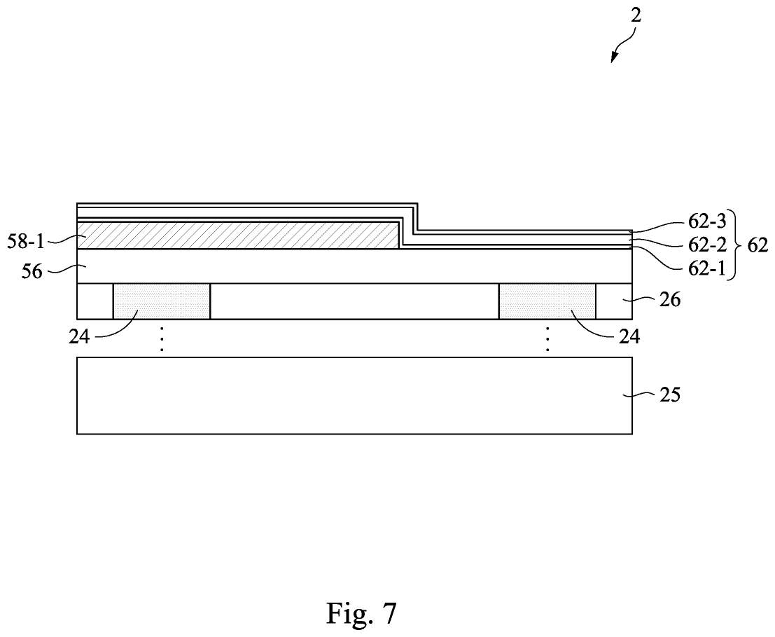

Reference is made to FIG. 7. A third dielectric layer 62-3 is formed on the second dielectric layer 62-2. In some embodiments, the formation process of the third dielectric layer 62-3 may include ALD, CVD, or the like. The second dielectric layer 62-2 and third dielectric layer 62-3 include different compositions and different k-values. The second dielectric layer 62-2 is sandwiched between the first dielectric layer 62-1 and the third dielectric layer 62-3. The first dielectric layer 62-1, the second dielectric layer 62-2 and the third dielectric layer 62-3 collectively form a dielectric structure 62. The first, second and third dielectric layers 62-1, 62-2, 62-3 are high-k dielectric layers. In some embodiments, the second dielectric layer 62-2 may be a bulk high-k layer to increase an effective capacitance of an MIM capacitor. The second dielectric layer 62-2 has a k value greater than a k value of the first dielectric layer 62-1 and a k-value of the third dielectric layer 62-3. In some embodiments, the second dielectric layer 62-2 has the k value greater than 17. In some embodiments, the second dielectric layer 62-2 is made of HfO₂, ZrO₂, La₂O₃, HfZrOₓ, HfLaOₓ, ZrLaOₓ, or the like. In some embodiments, the first dielectric layer 62-1 and the third dielectric layer 62-3 each have a k value greater than about 13.4. In some embodiments, the k value of the first dielectric layer 62-1 and the k value of the third dielectric layer 62-3 each are in a range from about 13.4 to about 17. In some embodiments, the second dielectric layer 62-2 has a thickness greater than a thickness of the first dielectric layer 62-1 and a thickness of the third dielectric layer 62-3. In some embodiments, the second dielectric layer 62-2 has a thickness in a range from about 1 Å to about 500 Å, the first dielectric layer 62-1 has a thickness in a range from about 1 Å to about 100 Å, and the third dielectric layer 62-3 has a thickness in a range from about 1 Å to about 100 Å.

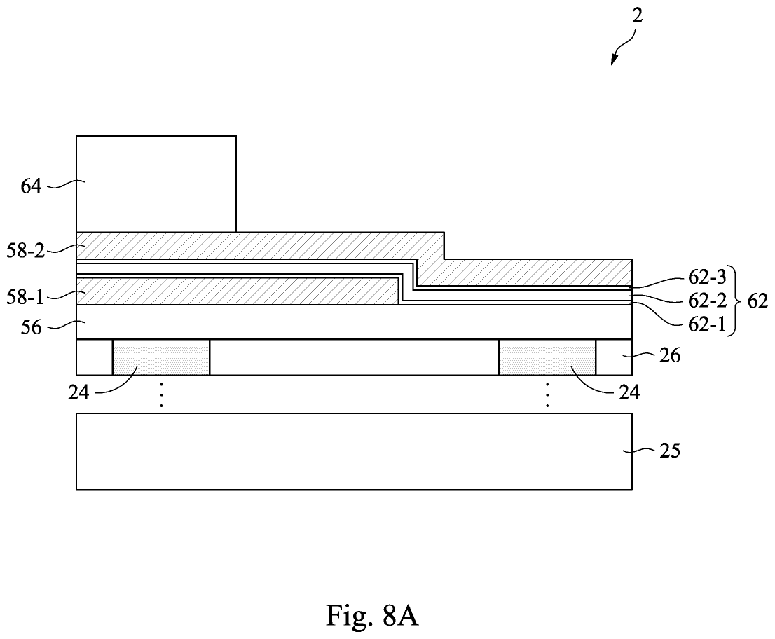

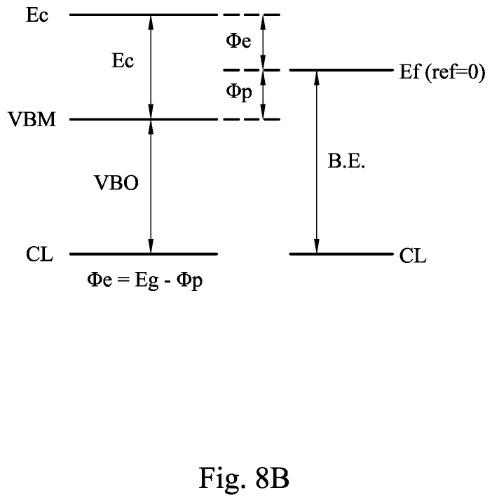

Referring to FIG. 8A, a capacitor electrode 58-2 is deposited as a blanket layer over the dielectric structure 62. In accordance with some embodiments, the capacitor electrode 58-2 is formed of or includes the same or similar material (such as TiN or TaN) as the capacitor electrode 58-1. FIG. 8B shows a band diagram of the dielectric structure 62 and the capacitor electrodes 58-1, 58-2 in accordance with some embodiments. Reference is made to FIGS. 8A and 8B. It is found that the electron barrier height (Φe) is related to the MIM device at the MIM interface. As the electron barrier height (Φe) increases, the leakage current may be decreased. The electron barrier height (Φe) may be defined as the energy gap (Eg) minus the hole barrier height (Φp). Since the k-value is in positive relation to a reciprocal of an energy gap, by using the first dielectric layer 62-1 and the third dielectric layer 62-3 with the k value lower than the k value of the second dielectric layer 62-2, an electron/conduction barrier height can be increased, resulting in the decreased leakage current. In other words, the first dielectric layer 62-1 and the third dielectric layer 62-3 each include higher conduction band barrier height than the second dielectric layer 62-2 to block electrons and avoid leakage current, and hence improve the reliability of the MIM capacitor. In some embodiments, the leakage current has a reduced amount of about 88%. The conduction band barrier height and the electron barrier height are interchangeable herein.

For example, the first dielectric layer 62-1 and the third dielectric layer 62-3 each have an interface conduction band (Ec) barrier height greater than about 1.4 eV, and can be referred to as band diagram modulating (BDM) high-k layers. In some embodiments, the crystallization temperatures of the first and third dielectric layers 62-1, 62-3 are greater than about 400° C. In some embodiments, the first dielectric layer 62-1 and the third dielectric layer 62-3 may include Y₂O₃, La₂O₃, LaYOₓ, Gd₂O₃, Si₃N₄, or the like. In some embodiments where the first dielectric layer 62-1 and the third dielectric layer 62-3 are made of Y₂O₃ and the second dielectric layer 62-2 is made of HfOₓ, the dielectric structure 62 can provide an electron barrier height in a range from about 2.7 eV to about 3.6 eV, such as about 3.6 eV as measured by an X-ray Photoelectron Spectroscopy (XPS) and a breakdown voltage (V_{BD}) of about 6.4±1 V.

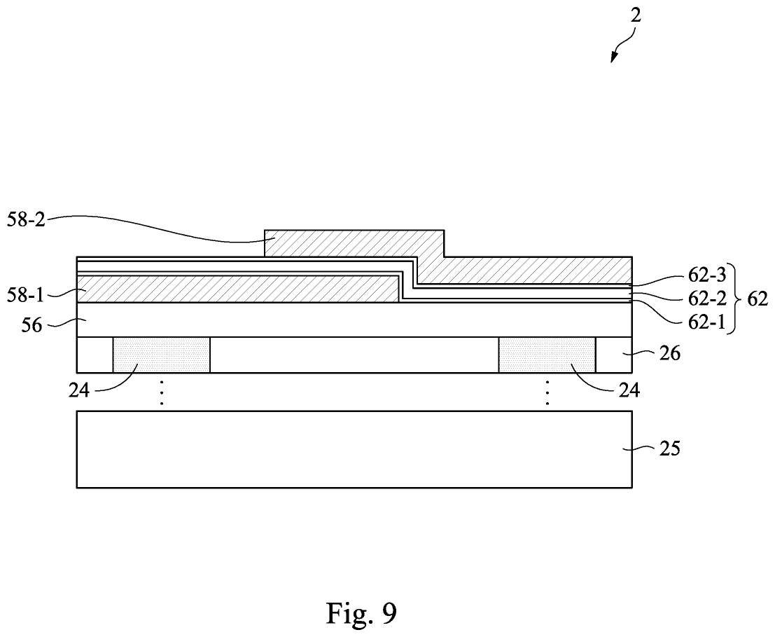

A patterned etching mask 64 is then formed on the capacitor electrode 58-2. The patterned etching mask 64 may be a single layer formed of a photoresist, or may be a tri-layer etching mask. The capacitor electrode 58-2 is then etched using the etching mask 64 to define the patterns. In the etching of the capacitor electrode 58-2, the third dielectric layer 62-3 is used as an etch stop layer. The third dielectric layer 62-3 is exposed after etching the capacitor electrode 58-2. The etching mask 64 is then removed. The resulting structure is shown in FIG. 9.

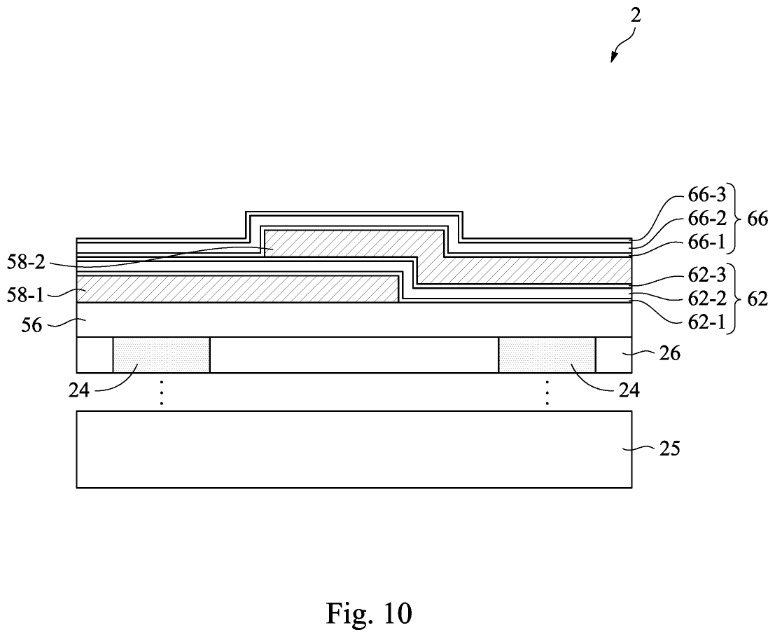

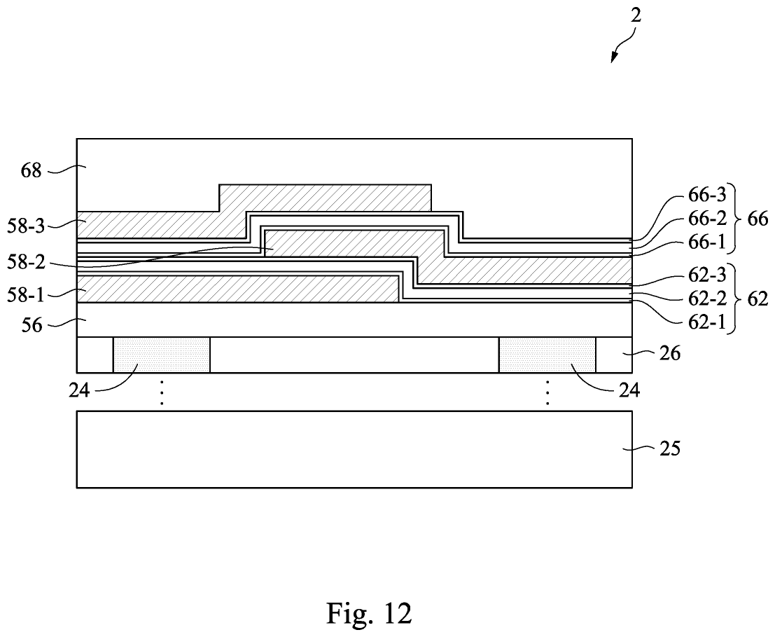

In accordance with some embodiments, more capacitor electrodes and dielectric structures (as shown in FIGS. 10-12) are formed over the structure shown in FIG. 9 to increase the capacitance of the resulting capacitor. In accordance with alternative embodiments, no more capacitor electrodes and dielectric structures are formed over capacitor electrode 58-2, and the process flow proceeds to the process shown in FIG. 12.

Referring to FIG. 10, a dielectric structure 66 is formed on the capacitor electrode 58-2. The structure and the formation process of the dielectric structure 66 may be essentially the same as that of the dielectric structure 62, and the structure and the formation process may be found referring to FIGS. 5 through 7 and the related discussion. For example, the dielectric structure 66 may include a first dielectric layer 66-1, a second dielectric layer 66-2 and a third dielectric layer 66-3, which are similar to the first dielectric layer 62-1, the second dielectric layer 62-2 and the third dielectric layer 62-3 in terms of composition. The dielectric structure 66 extends over a top surface of the capacitor electrode 58-2, along sidewalls of the capacitor electrode 58-2 and over a top surface of the dielectric structure 62.

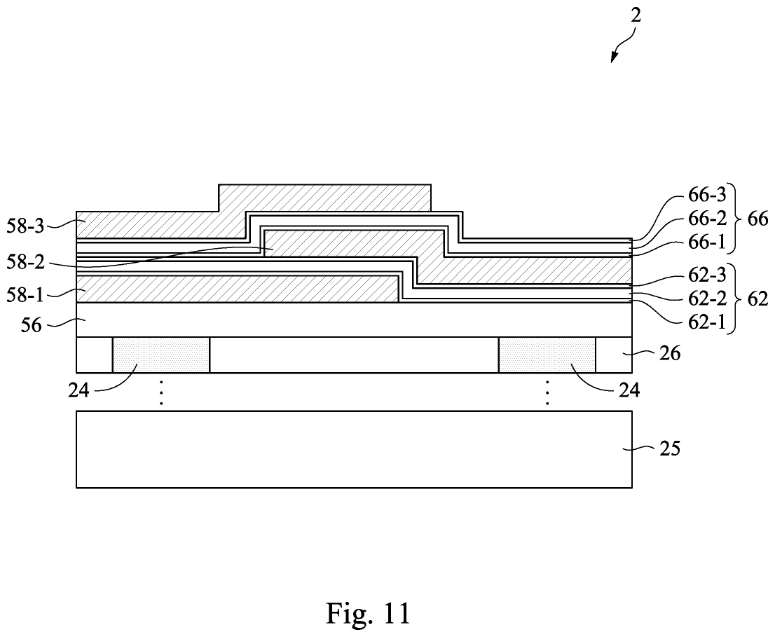

FIG. 11 illustrates the formation of a capacitor electrode 58-3. It is appreciated that the structure illustrated in FIG. 11 is an example, and the capacitor may include more or fewer capacitor electrodes and dielectric structures. The formation of the capacitor electrode 58-3 may be the same or similar to the formation of capacitor electrode 58-1, and the materials and the formation processes may be found referring to FIGS. 5 through 7.

Next, as shown in FIG. 12, a dielectric layer 68 is deposited. In accordance with some embodiments, the dielectric layer 68 is formed of or comprises USG, silicon nitride, silicon oxide, silicon oxynitride, silicon oxycarbide, or the like. In accordance with alternative embodiments, the dielectric layer 68 may be formed of a low-k dielectric material, for example, when the resulting capacitor is one of the capacitors 46A and 46B (FIG. 1). In accordance with yet alternative embodiments, the dielectric layer 68 may be polymer layer 36 or 42 in the embodiments shown in FIG. 1. After the deposition of the dielectric layer 68, a planarization process such as a Chemical Mechanical Polish (CMP) process or a mechanical grinding process may be performed, so that the top surface of dielectric layer 68 is planar.

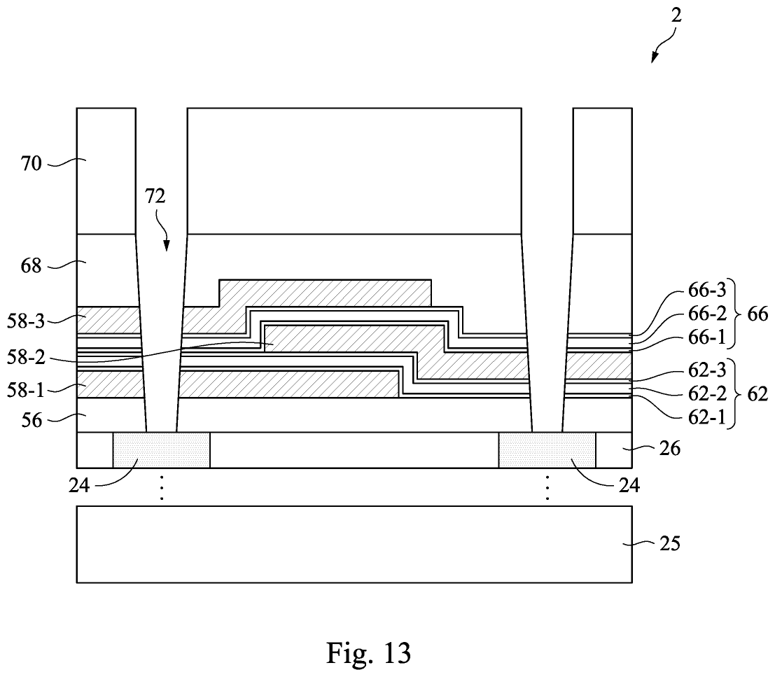

FIG. 13 illustrates a photo lithography process. An etching mask 70 is first formed. In accordance with some embodiments, the etching mask 70 includes a photoresist, and may include anti-reflective coating therein. The etching mask 70 may have a single-layer structure, a dual-layer structure, a tri-layer structure, or the like. Next, etching processes are performed to etch the dielectric layer 68, the capacitor electrodes 58-1, 58-2, 58-3 and the dielectric structures 62, 66 and the dielectric layer 56, so that the conductive features 24 are revealed to contact openings 72.

The etching of the dielectric layer 68, the capacitor electrodes 58-1, 58-2, 58-3 and the dielectric structures 62, 66 and the dielectric layer 56 may use the similar etching chemicals (such as gases or chemical solutions) as what is used for patterning the dielectric layer 68, the capacitor electrodes 58-1, 58-2, 58-3 and the dielectric structures 62, 66 and the dielectric layer 56. A bias power is applied, so that the etching is anisotropic. The etching mask 70 is then removed.

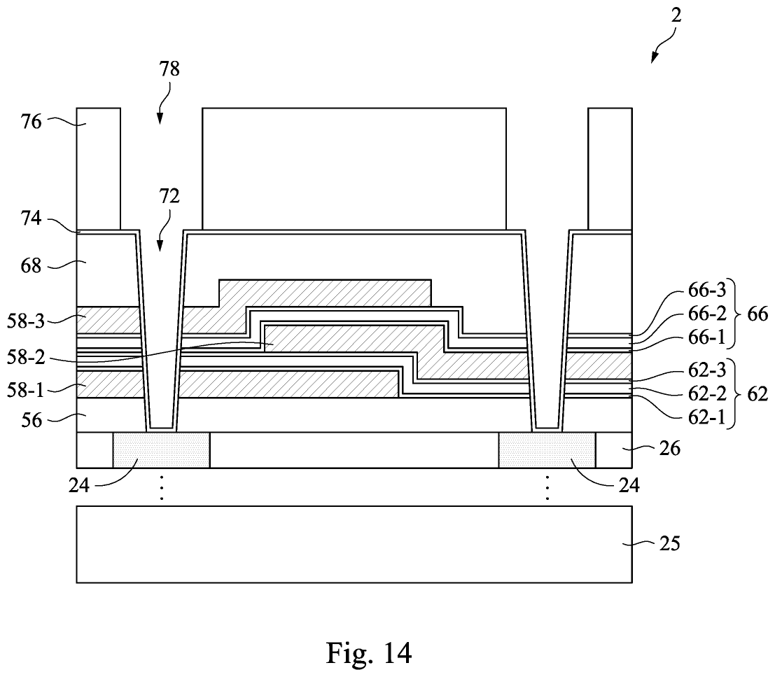

FIG. 14 illustrates the deposition of a metal seed layer 74. In accordance with some embodiments, the metal seed layer 74 includes a titanium layer and a copper layer over the titanium layer. In accordance with alternative embodiments, the metal seed layer 74 includes a copper layer in contact with the dielectric layer 68 and in contact with sidewalls of the capacitor electrodes 58-1, the 58-2, 58-3, the dielectric layer 56 and a top surface of the conductive features 24. The deposition process may be performed using Physical Vapor Deposition (PVD), CVD, Metal Organic Chemical Vapor Deposition (MOCVD), or the like.

FIG. 14 further illustrates the formation of patterned plating mask 76. In accordance with some embodiments, the plating mask 76 is formed of or includes photoresist. Openings 78 are formed in the patterned plating mask 76 to reveal the metal seed layer 74.

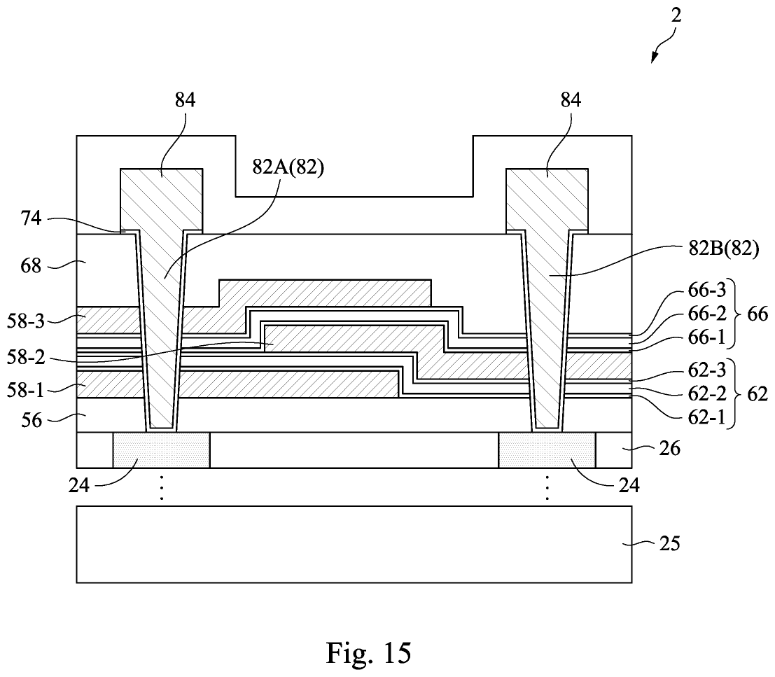

FIG. 15 illustrates the deposition of a conductive material on the metal seed layer 74. The conductive material is filled into the contact openings 72 and the openings 78. Contact plugs 82 and conductive lines 84 are thus formed. In accordance with some embodiments, the formation of the contact plugs 82 and the conductive lines 84 includes a plating process, which may include an electrochemical plating process, an electroless plating process, or the like. The conductive material may include copper, aluminum, nickel, tungsten, or the like, or alloys thereof.

Next, the plating mask 76 as shown in FIG. 14 is removed. In a subsequent process, an etching process is performed to remove the portions of the metal seed layer 74 that are not protected by the overlying contact plugs 82 and conductive lines 84. The resulting structure is also shown in FIG. 15. The remaining metal seed layer 74 becomes parts of the contact plugs 82 and conductive lines 84. The contact plugs 82 include contact plugs 82A and 82B, which are connected to opposing capacitor electrodes of the capacitor 46.

The contact plug 82A is electrically connected to, and electrically shorts, the capacitor electrodes 58-1 and 58-3. The contact plug 82B is electrically connected to, and electrically shorts, the capacitor electrode 58-2. Accordingly, the capacitor 46 is formed, which include the capacitor electrodes 58-1 and 58-3 collectively as a first capacitor electrode, and the capacitor electrode 58-2 collectively as a second capacitor electrode.

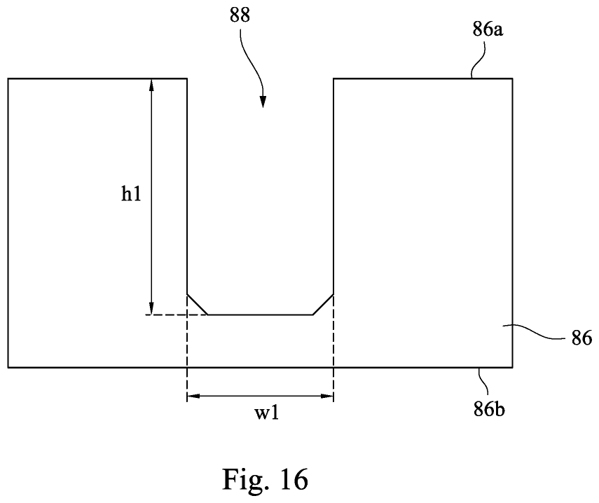

FIGS. 16-19 illustrate cross-sectional views of intermediate stages in the formation of a deep trench capacitor (DTC) in accordance with some embodiments. Reference is made to FIG. 16. The exemplary structure according to an embodiment of the present disclosure is illustrated, which comprises a substrate 86 having a planar top surface. The substrate 86 may be a semiconductor substrate including a semiconductor material. The substrate 86 may have a front surface 86a and a backside surface 86b. The front surface 86a may be parallel to the backside surface 86b. In one embodiment, the substrate 86 may include a semiconductor wafer that may be diced into semiconductor dies after formation of the deep trench. For example, the substrate 86 may include a semiconductor substrate including single crystalline silicon.

A deep trench 88 vertically extending into the substrate 86 may be formed by forming a patterned etch mask layer on the front surface 86a of the substrate 86. The pattern in the patterned etch mask layer may be transferred into an upper portion of the substrate 86. An optional pad dielectric layer (not shown) such as a silicon oxide pad layer may be formed on the front side surface, i.e., the top surface, of the substrate 86 prior to formation of the patterned etch mask layer. The deep trench 88 includes a critical dimension (CD) w1 in a range from about 0.05 μm to about 0.5 μm, and a depth h1 in a range from about 1 μm to about 20 μm. In some embodiments, the deep trench 88 has an aspect ratio in a range from about 2 to about 400.

The patterned etch mask layer may be formed by depositing a blanket etch mask layer, forming a lithographically patterned photoresist layer over the blanket etch mask layer, and by transferring the pattern in the lithographically patterned photoresist layer to the blanket etch mask layer using an anisotropic etch process such as a reactive ion etch process.

An anisotropic etch process may be performed to transfer the pattern in the patterned etch mask layer through an upper portion of the substrate 86 to form the deep trench 88. For example, a reactive ion etch process using a combination of gases including HBr, NF₃, O₂, and SF₆ may be used to form the deep trench 88. The horizontal cross-sectional shape of the deep trench 88 may have a shape of a circle, an ellipse, a rectangle, a rounded rectangle, an annulus having an inner periphery and an outer periphery of various shapes, or of any two-dimensional shape that defines an enclosed volume. Generally, at least one deep trench 88 extending downward from a top surface of the substrate 86 may be formed in the substrate 86.

Generally, at least one deep trench 88 vertically extending from the front surface 86a toward the backside surface 86b may be formed. In one embodiment, the at least one deep trench 88 may be a plurality of deep trenches 88.

The photoresist layer may be removed prior to the anisotropic etch process that forms the deep trench 88, or may be consumed during the anisotropic etch process that forms the deep trench 88. The patterned etch mask layer and the optional dielectric pad layer may be subsequently removed, for example, by a respective isotropic etch process such as a wet etch process.

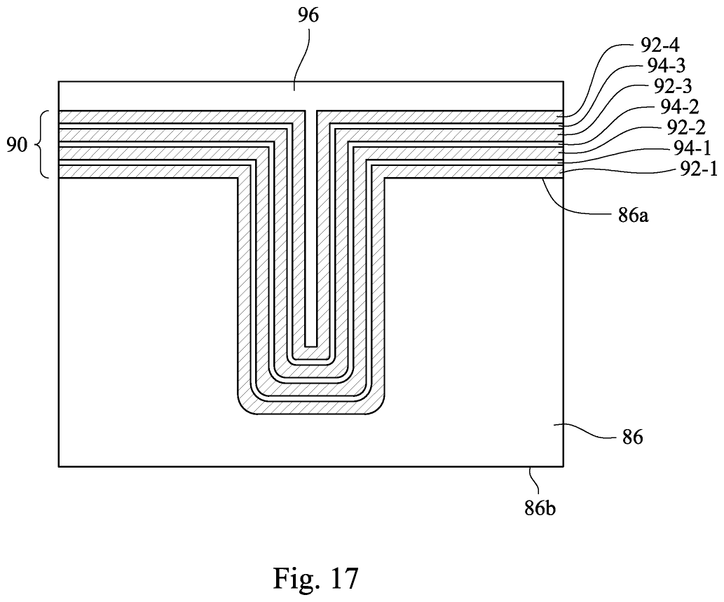

Referring to FIG. 17, in some embodiments, a dielectric liner (not shown) may be formed on a physically exposed surface of the substrate 86 including the top surface of the substrate 86 and sidewalls of the deep trench 88. The dielectric liner may include a dielectric material that provides electrical isolation between a deep trench capacitor which would be subsequently formed and the substrate 86. For example, the dielectric liner may include silicon oxide, silicon nitride, silicon oxynitride, and/or a dielectric metal oxide. Other suitable materials within the contemplated scope of disclosure may also be used. In an illustrative example, the dielectric liner may include a silicon oxide layer formed by thermal oxidation of surface portions of the substrate 86 that includes silicon.

An alternating layer stack 90 of capacitor electrodes 92-1, 92-2, 92-3, 92-4 and dielectric structures 94-1, 94-2, 94-3 may be formed by a respective conformal deposition process. The capacitor electrode 92-1 extends over a top surface (e.g., the front surface 86a) of the substrate 86, along opposite sidewalls of the deep trench 88 and over a bottom of the deep trench 88. In some other embodiments, the alternating layer stack 90 includes at least one of the capacitor electrodes 92-1, 92-2, 92-3, 92-4 interlaced with at least one of the dielectric structures 94-1, 94-2, 94-3, and continuously extending over the top surface of the substrate 86 and into the deep trench 88 (see FIG. 16). The alternating layer stack 90 continuously extends into the deep trench 88, and a cavity is present in an unfilled volume of the deep trench 88.

Each of the capacitor electrodes 92-1, 92-2, 92-3, 92-4 may include a metallic material, which may comprise, and/or consist essentially of, a conductive metallic nitride, an elemental metal, or an intermetallic alloy. In one embodiment, the capacitor electrodes 92-1, 92-2, 92-3, 92-4 comprises, and/or consists essentially of, a conductive metallic nitride material, which may be a metallic diffusion barrier material. For example, the capacitor electrodes 92-1, 92-2, 92-3, 92-4 may include, and/or may consist essentially of, a conductive metallic nitride material such as TiN, TaN, or WN. Other suitable materials within the contemplated scope of disclosure may also be used.

Use of a metallic diffusion barrier material for the capacitor electrodes 92-1, 92-2, 92-3, 92-4 may be advantageous because diffusion of metallic elements through the dielectric structures 94-1, 94-2, 94-3 may cause deleterious effects for deep trench capacitors. Each capacitor electrodes 92-1, 92-2, 92-3, 92-4 may be formed by a conformal deposition process such as chemical vapor deposition (CVD) or atomic layer deposition (ALD). In one embodiment, each capacitor electrodes 92-1, 92-2, 92-3, 92-4 may have the same material composition and the same thickness. In another embodiment, each capacitor electrodes 92-1, 92-2, 92-3, 92-4 may have the same material composition but have varying thicknesses. In yet another embodiment, each capacitor electrodes 92-1, 92-2, 92-3, 92-4 may have different material composition and the same thickness. In yet another embodiment, the capacitor electrodes 92-1, 92-2, 92-3, 92-4 may have different material composition and different thicknesses.

Each of the dielectric structures 94-1, 94-2, 94-3 may be a multilayer structure which is similar to the dielectric structure 62 with regard to FIG. 7, and hence the description thereof is omitted herein. By using the dielectric structures 94-1, 94-2, 94-3, the leakage current can be reduced, and hence improves the reliability of the MIM capacitor.

While the present disclosure is described using an embodiment in which the alternating layer stack 90 of the capacitor electrodes 92-1, 92-2, 92-3, 92-4 and the dielectric structures 94-1, 94-2, 94-3 include four capacitor electrodes 92-1, 92-2, 92-3, 92-4 and three dielectric structures 94-1, 94-2, 94-3, embodiments are expressly contemplated herein in which different numbers of capacitor electrodes 92-1, 92-2, 92-3, 92-4 and different numbers of three dielectric structures 94-1, 94-2, 94-3 may be used within the alternating layer stack 90.

The capacitor electrodes 92-1, 92-3 may be used to form a primary electrode assembly that functions as a primary node, i.e., a first node, of a deep trench capacitor. The capacitor electrodes 92-2, 92-4 may be used to form a secondary electrode assembly that functions as a secondary node, i.e., a second node, of a deep trench capacitor.

In embodiments in which any void is present in the deep trench 88, a fill layer 96 may be deposited to fill or partially fill remaining voids in the deep trench 88. In some embodiments, the fill layer 96 includes a conductive material similar to the material of the capacitor electrodes 92-1, 92-2, 92-3, 92-4.

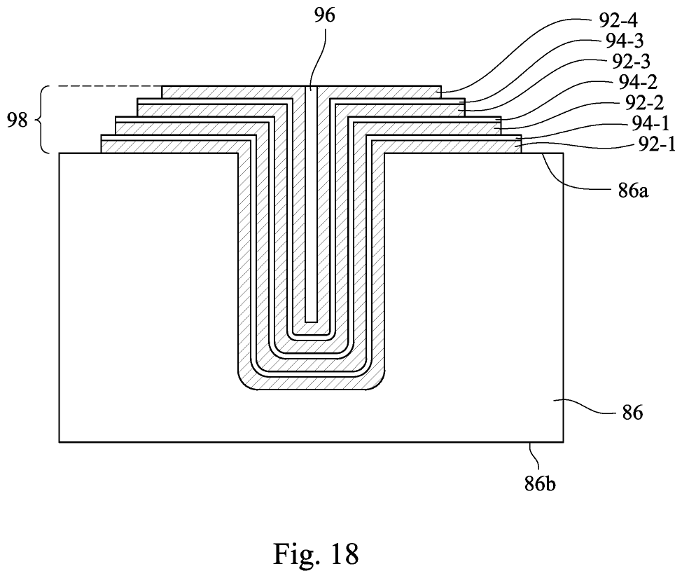

Referring to FIG. 18, a multi-step etch is performed to the alternating layer stack 90 and the fill layer 96 to form a step structure above the front surface 86a of the substrate 86. The capacitor electrodes 92-1, 92-2, 92-3, 92-4 are in succession recessed one from another, exposing peripheral regions for formed contacting structures. After performing the multi-step etch, an MIM capacitor 98 is formed.

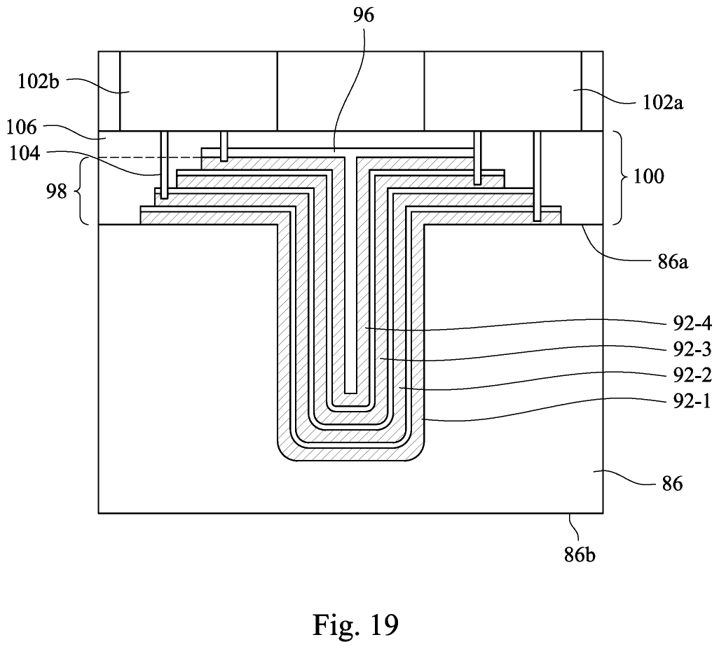

Referring to FIG. 19, an interconnect structure 100 is disposed over the substrate 86 and the MIM capacitor 98. The interconnect structure 100 is formed in a back-end-of-line (BEOL) operation and is configured to electrically coupled the MIM capacitor 98 and other electrical components in the substrate 86 with another layer (i.e., overlying bonding pads 102a, 102b). In some embodiments, the interconnect structure 100 electrically couples the MIM capacitor 98 with the overlying bonding pads 102a, 102b. The interconnect structure 100 may include conductive vias 104 and an interlayer dielectric (ILD) layer 106. The conductive vias 104 are formed in the ILD layer 106 and may be electrically coupled to the capacitor electrodes 92-1, 92-2, 92-3, 92-4 respectively. The conductive vias 104 may be formed of conductive materials, such as aluminum, gold, silver and tungsten. The ILD layer 106 may be formed from a variety of dielectric materials, such as oxide (e.g., Ge oxide), oxynitride (e.g., GaP oxynitride), silicon dioxide (SiO₂), nitrogen-bearing oxide (e.g., nitrogen-bearing SiO₂), nitrogen-doped oxide (e.g., N₂-implanted SiO₂), silicon oxynitride (SiₓO_{y}N_{z}), and the like.

The bonding pads 102a, 102b are disposed over the interconnect structure 100. The bonding pads 102 are configured to electrically connect the devices or components with other devices on the substrate 86. The bonding pads 102a, 102b may be metal lines coupled to a reference power level, such as the power supply level or the ground level. The charging and discharging operations for the MIM capacitor 98 may be performed through the bonding pads 102a, 102b. In some embodiments, the bonding pad 102a may supply the capacitor electrodes 92-1 and 92-3 with a high voltage level while the bonding pad 102b may connect the capacitor electrodes 92-2, 92-4 to a low voltage level.

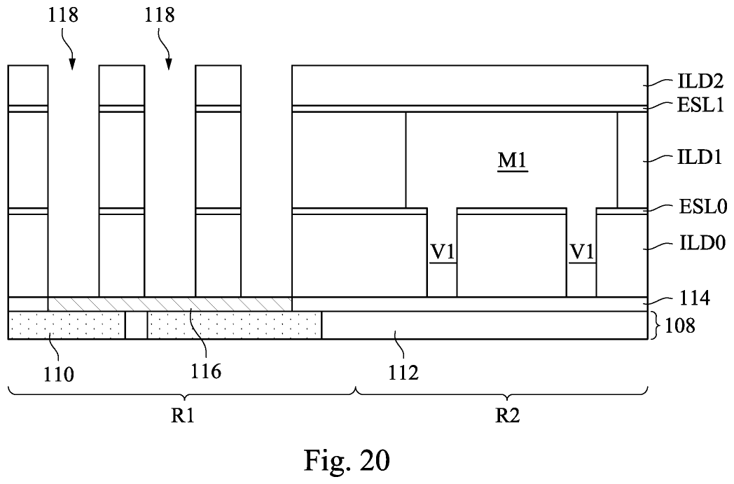

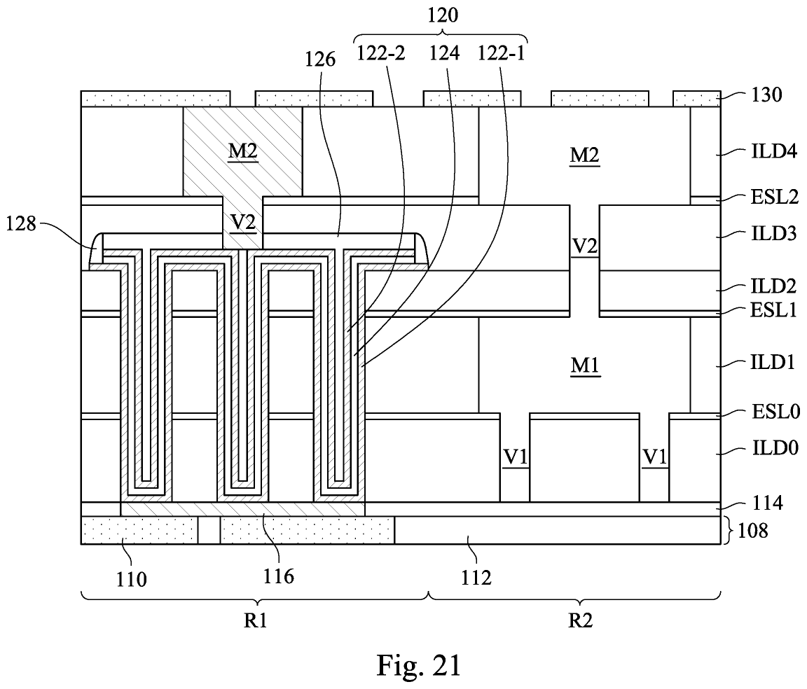

FIGS. 20-21 illustrate cross-sectional views of a semiconductor structure in accordance with some embodiments. Reference is made to FIG. 21. In some embodiments, an interconnect structure 108 having an inter-layer dielectric (ILD) layer or inter-metal dielectric layer (IMD) layer 112 with a lower metallization pattern 110 is formed over a substrate (not shown in FIG. 21). The ILD layer 112 may be silicon oxide, fluorinated silica glass (FSG), carbon doped silicon oxide, tetra-ethyl-ortho-silicate (TEOS) formed oxide, phosphosilicate glass (PSG), borophosphosilicate glass (BPSG), Black Diamond® (Applied Materials of Santa Clara, Calif.), amorphous fluorinated carbon, low-k dielectric material, the like or combinations thereof. The lower metallization patterns 110 may be aluminum, aluminum alloy, copper, copper alloy, titanium, titanium nitride, tantalum, tantalum nitride, tungsten, the like, and/or combinations thereof. Formation of the lower metallization patterns 110 and the ILD layer 112 may be a dual-damascene process and/or a single-damascene process.

In some embodiments, a dielectric layer 114 is formed over the interconnect structure 108. The dielectric layer 114 may be formed by acceptable deposition techniques, such as chemical vapor deposition (CVD), atomic layer deposition (ALD), physical vapor deposition (PVD), the like, and/or a combination thereof. A chemical-mechanical polish (CMP) process is optionally performed to the dielectric layer 114, until a desirable thickness is achieved. The dielectric layer 114 can be, for example, silicon dioxide layer, silicon carbide layer, silicon nitride layer, silicon oxycarbide layer, silicon oxynitride layer, low-k dielectric (e.g., having a dielectric constant of less than about 3.9) layer, extreme low-k (ELK) dielectric (e.g., having a dielectric constant of less than about 2.5) layer, the like, or combinations thereof.

A metal line 116 is then formed within the dielectric layer 114. An exemplary formation method of the metal line 116 includes etching an opening in the dielectric layer 114, filling metal into the openings, and performing a planarization process, such as a CMP process, to remove excess materials of the filling metal outside the opening in the dielectric layer 114. The remaining filling metal in the opening in the dielectric layer 114 can serve as the metal line 116. In some embodiments, the metal line 116 is electrically connected to an underlying electrical component, such as a transistor, through the lower metallization patterns 110. In some embodiments, the filling metal is titanium (Ti), tantalum (Ta), platinum (Pt), ruthenium (Ru), tungsten (W), aluminum (Al), copper (Cu), the like, and/or combinations thereof. Formation of the filling metal may be exemplarily performed using CVD, PVD, ALD, the like, and/or a combination thereof.

In some embodiments, included in integrated circuit is a plurality of ILD layers ILD0, ILD1, ILD2 as spanning a logic region R2 and a capacitor region R1 of the interconnect structure 108. The ILD layers ILD0, ILD1, ILD2 may provide electrical insulation as well as structural support for the various features of the integrated circuit during many fabrication process steps. The ILD layer ILD0 between the metallization layer M1 and the metal vias V1 may include an etch stop layers ESL0 to signaling the termination point of an etching process and protect any underlying layer or layers during the etching process. An etch stop layer ESL1 may be formed between the ILD layer ILD2 and the ILD layer ILD1.

In FIG. 20, a plurality of deep trenches 118 are formed in the ILD layers ILD0, ILD1, ILD2 and the etch stop layers ESL0, ESL1. The metal line 116 is exposed through the plurality of deep trenches 118.

Referring to FIG. 21, an alternating layer stack of a lower metallic electrode layer, a dielectric stack and an upper metallic electrode layer may be formed in the trenches by conformal deposition process. The lower metallic electrode layer, the dielectric stack and the upper metallic electrode layer are similar to the capacitor electrode 92-1, the dielectric structure 94-1 and the capacitor electrode 92-2 with regard to FIG. 17 in terms of composition and formation method thereof, and thus the description thereof is omitted herein. In some embodiments, the upper metallic electrode layer and the dielectric stack are etched to expose a top surface of the lower metallic electrode layer. Referring to FIG. 21, an MIM capacitor 120 is formed in the deep trenches 118. The MIM capacitor includes a capacitor electrode 122-1, a dielectric structure 124 and a capacitor electrode 122-2 formed in sequence. The capacitor electrode 122-1, a dielectric structure 124 and a capacitor electrode 122-2 are similar to the capacitor electrode 58-1, the dielectric structure 62 and the capacitor electrode 158-2 with regard to FIG. 8A in terms of composition and formation method thereof. A fill layer 126 may be deposited to fill or partially fill remaining voids in the deep trenches 118. The fill layer 126, the capacitor electrode 122-2 and the dielectric structure 124 may be pattered to expose a top surface of the capacitor electrode 122-1, for example, using a dry etching process including an ion beam etch (IBE) process or the like.

A spacer layer is formed over a top surface of the ILD layer ILD2, along sidewalls of the dielectric structure 124, along sidewalls of the capacitor electrode 122-2, over a top surface and along a sidewall of the capacitor electrode 122-1. In some embodiments, the spacer layer may include SiN, the like, or a combination thereof, and may be formed using CVD, ALD, or PVD or the like, and/or combinations thereof. An etching process is performed to etch the spacer layer into spacers 128. The etching process may be an anisotropic etch process. After the etching process, the top surface of the fill layer 126, the sidewall of the capacitor electrode 122-1 and the top surface of the ILD2 are exposed. The spacers 128 remain on and are in contact with the sidewalls of the fill layer 126, the dielectric structure 124 and the capacitor electrode 122-2 and a portion of the top surface of the capacitor electrode 122-1. The spacers laterally surround the fill layer 126, the dielectric structure 124 and the capacitor electrode 122-2.

An ILD layer ILD3, an etch stop layer ESL2 and an ILD layer ILD4 are then formed on the MIM capacitor 120 and the ILD layer ILD2. In the logic region R2, a via V2 is formed in the ILD layer ILD3, ILD2, and a metallization layer M2 is formed in the ILD layer ILD4 and the etch stop layer ESL2. In the capacitor region R1, the via V2 is formed in the ILD layer ILD2 and the fill layer 126, and the metallization layer M2 is formed in the ILD layer ILD4 and the etch stop layer ESL2. Formation of the via V2 and the metallization layer M2 may be formed by etching openings in the ILD layers ILD4, ILD3, ILD2, the etch stop layer ESL1, ESL2 and the fill layer 126, and then filling one or more metals in the openings, so that the vias V2 can reach on the metallization layer M1 in the logic region R2 and the capacitor electrode 122-2 in the capacitor region R1. A plurality of bonding pads 130 can be formed on the ILD layer ILD4 and be arranged side by side or in a staggered form.

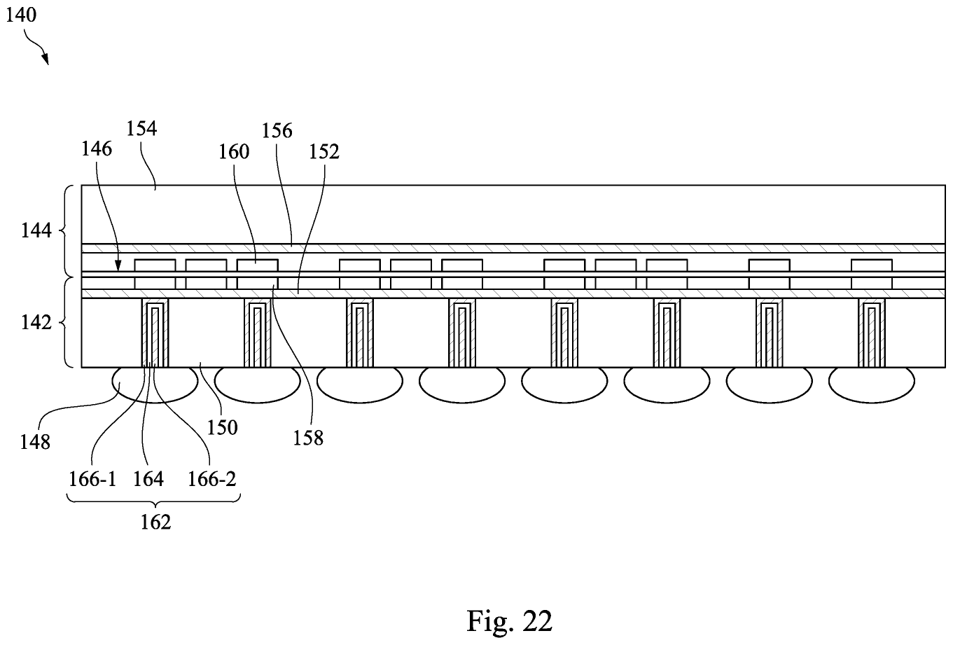

FIG. 22 illustrates a cross-sectional view of a 3D IC structure 140 in accordance with some embodiments. Reference is made to FIG. 22. The 3D IC structure 140 may include a first IC die 142, a second IC die 144, an interface 146 and a plurality of package bumps 148. The first IC die 142 may include a first functional element (e.g., a device, not shown), a first substrate 150 and a first IC die horizontal top metal layer 152. Similarly, the second IC die 144 may include a second functional element (e.g., a device, not shown), a second substrate 154 and a second die horizontal top metal layer 156. The second IC die 144 may be stacked on the first IC die 142, for example, in a face to face (F2F) configuration. In other words, the second IC die 144 is bonded to the first IC die 142.

The interface 146 may be disposed between the first IC die 142 and the second IC die 144. For example, the interface 146 may be disposed between the first IC die horizontal top metal layer 152 of the first IC die 142 and the second die horizontal top metal layer 156 of the second IC die 144. The interface 146 may include a plurality of hybrid layer pins 160 corresponding to the second IC die 144 and a plurality of hybrid layer bumps 158 corresponding to the first IC die 142. The hybrid layer pins 160 may respectively and correspondingly connect to the hybrid layer bumps 158. The interface 146 may provide a pathway for electrical power between the first IC die horizontal top metal layer 152 and the second IC die horizontal top metal layer 156.

The second IC die 144 includes deep trench capacitors (DTCs) 162. The first IC die horizontal top metal layer 152 is coupled to the DTCs 162. The DTCs 162 are coupled to the package bumps 148. The DTCs 162 may be formed and connected in parallel to provide a large capacitance and to increase the capacitance density, allowing construction of various devices such as high quality power delivery networks (PDN). The DTCs 162 are similar to the MIM capacitor 98 is terms of structure and composition with regard to FIG. 18. For example, the DTCs 162 may include a dielectric structure 164 sandwiched between capacitor electrodes 166-1, 166-2. In other words, the capacitor electrode 166-1, the dielectric structure 164 and the capacitor electrode 166-2 are stacked in sequence in the first substrate 150. The dielectric structure 164 is a multilayer structure including a first dielectric layer, a second dielectric layer and a third dielectric layer in which the second dielectric layer is sandwiched between the first dielectric layer and the third dielectric layer. The second dielectric layer has a k-value greater than the first and second dielectric layers. The first dielectric layer and the third dielectric layer each include higher conduction band barrier height than the second dielectric layer to avoid leakage current and improve reliability of the MIM capacitor.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that by forming a dielectric structure including a multilayer structure including a first dielectric layer, a second dielectric layer and a third dielectric layer in which the second dielectric layer is sandwiched between the first dielectric layer and the third dielectric layer, and the first dielectric layer and the third dielectric layer each include higher conduction band barrier height than the second dielectric layer, leakage current is avoided. Another advantage is that reliability of the MIM capacitor is thus improved.

In some embodiments, a method of forming a capacitor includes the following steps. A first electrode is formed over a substrate. A first dielectric layer is formed over the first electrode. A second dielectric layer is formed over the first dielectric layer. The first dielectric layer has a conduction band barrier height higher than a conduction band barrier height of the second dielectric layer. A second electrode is formed over the second dielectric layer. In some embodiments, the second dielectric layer has a k value different from a k value of the first dielectric layer. In some embodiments, the second dielectric layer has a k value greater than a k value of the first dielectric layer. In some embodiments, the first dielectric layer comprises Y₂O₃, La₂O₃, LaYOₓ, Gd₂O₃, Si₃N₄, or a combination thereof. In some embodiments, the first dielectric layer comprises a conduction band barrier height greater than about 1.4 eV. In some embodiments, the first dielectric layer has a k value in a range from about 13.4 to about 17. In some embodiments, the method further comprises prior to forming the second electrode over the second dielectric layer, forming a third dielectric layer over the second dielectric layer, wherein the third dielectric layer has a k value less than a k value of the second dielectric layer. In some embodiments, the third dielectric layer has a conduction band barrier height greater than a conduction band barrier height of the second dielectric layer. In some embodiments, the third dielectric layer comprises Y₂O₃, La₂O₃, LaYOₓ, Gd₂O₃, Si₃N₄, or a combination thereof. 10. In some embodiments, the second dielectric layer comprises HfO₂, ZrO₂, La₂O₃, HfZrOₓ, HfLaOₓ, ZrLaOₓ, or a combination thereof. In some embodiments, the second dielectric layer has a k value greater than 17.

In some embodiments, a method of forming a capacitor includes the following steps. A substrate is etched to form a trench. A first electrode is formed in the trench, wherein the first electrode extends over a top surface of the substrate, along opposite sidewalls of the trench and over a bottom of the trench. A first dielectric layer is formed on the first electrode. A second dielectric layer is formed over the first dielectric layer, wherein the second dielectric layer has a conduction band barrier height less than a conduction band barrier height of the first dielectric layer. A second electrode is formed over the second dielectric layer. In some embodiments, the method further comprises forming a dielectric structure over the second electrode and forming a third electrode over the dielectric structure. The dielectric structure comprises a first sub layer and a second sub layer over the first sub layer, the second sub layer has a conduction band barrier height less than a conduction band barrier height of the first sub layer. In some embodiments, both of the second dielectric layer and the first dielectric layer comprise a k value greater than about 13.4. In some embodiments, the first dielectric layer comprises a k value less than about 17. In some embodiments, the method further comprises after forming the second dielectric layer over the first dielectric layer, forming a third dielectric layer over the second dielectric layer, wherein the third dielectric layer comprises a material different from a material of the second dielectric layer. In some embodiments, both of the second dielectric layer and the third dielectric layer comprise a k value greater than about 13.4.

In some embodiments, a 3D integrated circuit (IC) structure includes a first IC die, a second IC die bonded to the first IC die, and a plurality of package bumps. The first IC die comprises a plurality of deep trench capacitors. One of the plurality of deep trench capacitors comprises a first capacitor electrode, a dielectric structure and a dielectric structure. The dielectric structure comprises a first dielectric layer, a second dielectric layer and a third dielectric layer stacked in sequence over the first capacitor electrode. Each of the first dielectric layer and the third dielectric layer comprise a conduction band barrier height greater than a conduction band barrier height of the second dielectric layer. The plurality of package bumps is coupled to the plurality of deep trench capacitors. In some embodiments, the first dielectric layer has a k value lower than a k value of the second dielectric layer, and the third dielectric layer has a k value lower than a k value of the second dielectric layer. In some embodiments, the first dielectric layer and the third dielectric layer comprise Y₂O₃, La₂O₃, LaYOₓ, Gd₂O₃, Si₃N₄, or a combination thereof.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a capacitor, comprising:
forming a first electrode over a substrate;
forming a first dielectric layer over the first electrode;
forming a second dielectric layer over the first dielectric layer, wherein the first dielectric layer has a conduction band barrier height higher than a conduction band barrier height of the second dielectric layer; and
forming a second electrode over the second dielectric layer.

2. The method of claim 1, wherein the second dielectric layer has a k value different from a k value of the first dielectric layer.

3. The method of claim 1, wherein the second dielectric layer has a k value greater than a k value of the first dielectric layer.

4. The method of claim 1, wherein the first dielectric layer comprises Y₂O₃, La₂O₃, LaYOₓ, Gd₂O₃, Si₃N₄, or a combination thereof.

5. The method of claim 1, wherein the first dielectric layer comprises a conduction band barrier height greater than about 1.4 eV.

6. The method of claim 1, wherein the first dielectric layer has a k value in a range from about 13.4 to about 17.

7. The method of claim 1, further comprising:
prior to forming the second electrode over the second dielectric layer, forming a third dielectric layer over the second dielectric layer, wherein the third dielectric layer has a k value less than a k value of the second dielectric layer.

8. The method of claim 7, wherein the third dielectric layer has a conduction band barrier height greater than a conduction band barrier height of the second dielectric layer.

9. The method of claim 7, wherein the third dielectric layer comprises Y₂O₃, La₂O₃, LaYOₓ, Gd₂O₃, Si₃N₄, or a combination thereof.

10. The method of claim 1, wherein the second dielectric layer comprises HfO₂, ZrO₂, La₂O₃, HfZrOₓ, HfLaOₓ, ZrLaOₓ, or a combination thereof.

11. The method of claim 1, wherein the second dielectric layer has a k value greater than 17.

12. A method of forming a capacitor, comprising:
etching a substrate to form a trench;
forming a first electrode in the trench, wherein the first electrode extends over a top surface of the substrate, along opposite sidewalls of the trench and over a bottom of the trench;
forming a first dielectric layer on the first electrode;
forming a second dielectric layer over the first dielectric layer, wherein the second dielectric layer has a conduction band barrier height less than a conduction band barrier height of the first dielectric layer; and
forming a second electrode over the second dielectric layer.

13. The method of claim 12, further comprising:
forming a dielectric structure over the second electrode, wherein the dielectric structure comprises a first sub layer and a second sub layer over the first sub layer, the second sub layer has a conduction band barrier height less than a conduction band barrier height of the first sub layer; and
forming a third electrode over the dielectric structure.

14. The method of claim 12, wherein both of the second dielectric layer and the first dielectric layer comprise a k value greater than about 13.4.

15. The method of claim 12, wherein the first dielectric layer comprises a k value less than about 17.

16. The method of claim 12, further comprising:
after forming the second dielectric layer over the first dielectric layer, forming a third dielectric layer over the second dielectric layer, wherein the third dielectric layer comprises a material different from a material of the second dielectric layer.

17. The method of claim 16, wherein both of the second dielectric layer and the third dielectric layer comprise a k value greater than about 13.4.

18. A 3D integrated circuit (IC) structure, comprising:
a first IC die;
a second IC die bonded to the first IC die, wherein the first IC die comprises a plurality of deep trench capacitors, one of the plurality of deep trench capacitors comprises:
a first capacitor electrode;
a dielectric structure, wherein the dielectric structure comprises a first dielectric layer, a second dielectric layer and a third dielectric layer stacked in sequence over the first capacitor electrode, wherein each of the first dielectric layer and the third dielectric layer comprise a conduction band barrier height greater than a conduction band barrier height of the second dielectric layer; and
a second capacitor electrode over the dielectric structure; and
a plurality of package bumps coupled to the plurality of deep trench capacitors.

19. The structure of claim 18, wherein the first dielectric layer has a k value lower than a k value of the second dielectric layer, and the third dielectric layer has a k value lower than a k value of the second dielectric layer.

20. The structure of claim 18, wherein the first dielectric layer and the third dielectric layer comprise Y₂O₃, La₂O₃, LaYOₓ, Gd₂O₃, Si₃N₄, or a combination thereof.
